(19) United States
(12) Patent Application Publication
(10) Pub. No.: US 2012/0050117 A1
(43) Pub. Date: Mar. 1, 2012

(54) ELECTROMAGNETIC INTERFERENCE TEST DEVICE

(75) Inventors: JUN-WEI WANG, Shenzhen City (CN); CHUN-HUNG CHEN, Tu-Cheng (TW)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 12/889,425

(22) Filed: Sep. 24, 2010

(30) Foreign Application Priority Data
Aug. 27, 2010 (CN) 201010264767.7

(51) Int. Cl. G01R 29/08

(52) U.S. Cl. 343/703

(57) ABSTRACT

A test device for testing high frequency electromagnetic interference (EMI), the test device includes a measuring body and a probe device. The probe device includes a horn antenna, a handle, and a cable. The horn antenna detects high frequency EMI. The handle is attached to the horn antenna for feasibly holding the horn antenna. A first end of the cable is connected to the horn antenna, and a second end of the cable is connected to the measuring body.

### BACKGROUND

1. Technical Field

The present disclosure relates to test devices and, particularly, to a test device for testing electromagnetic interference (EMI).

2. Description of Related Art

High frequency EMI tests should be performed on electronic devices during manufacture. A typical EMI test device is fixed on a support member beside a production line to detect and measure the presence of EMI in an electronic device. However, because the test device is in a fixed position it may not accurately detect and measure EMI of all components of a passing electronic device.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present embodiments. Moreover, in the drawings, like reference numerals designate corresponding parts throughout the several views.

FIG. 1 is a schematic diagram of an exemplary embodiment of a test device for testing high frequency electromagnetic interference (EMI), the test device includes a probe device.

FIG. 2 is an exploded view of the probe device of FIG. 1, the probe device includes a horn antenna and a coaxial cable.

FIG. 3 is a front view of the horn antenna of FIG. 2.

FIG. 4 is a cross-sectional view of the coaxial cable of FIG. 2.

### DETAILED DESCRIPTION

The disclosure, including the drawings, is illustrated by way of example and not by limitation. It should be noted that references to “an” or “one” embodiment in this disclosure are not necessarily to the same embodiment, and such references mean at least one.

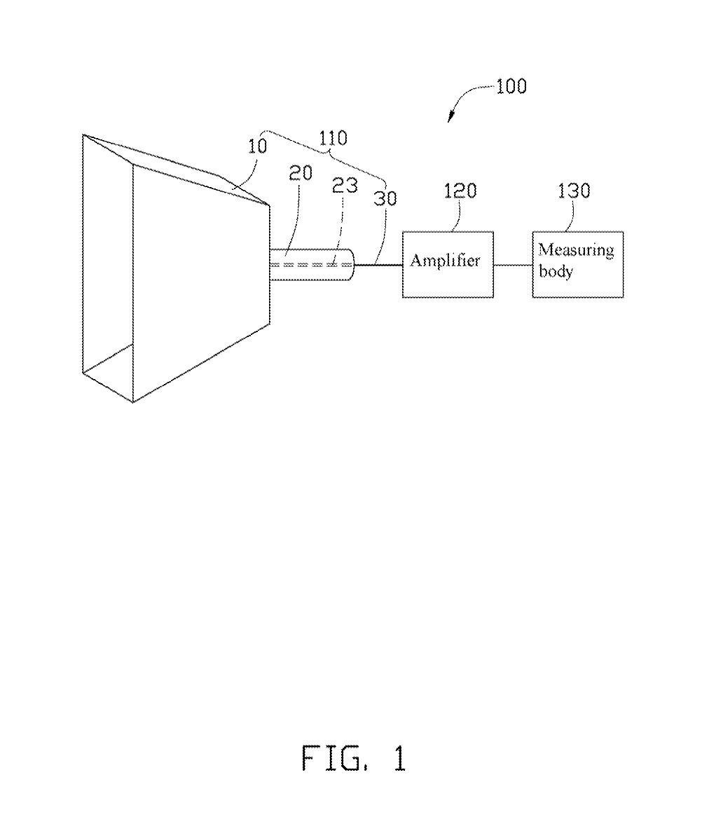

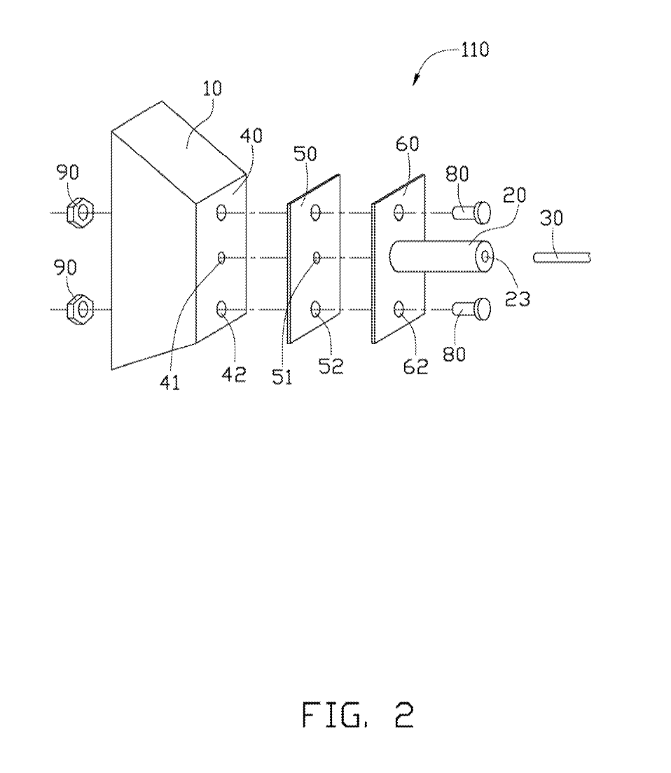

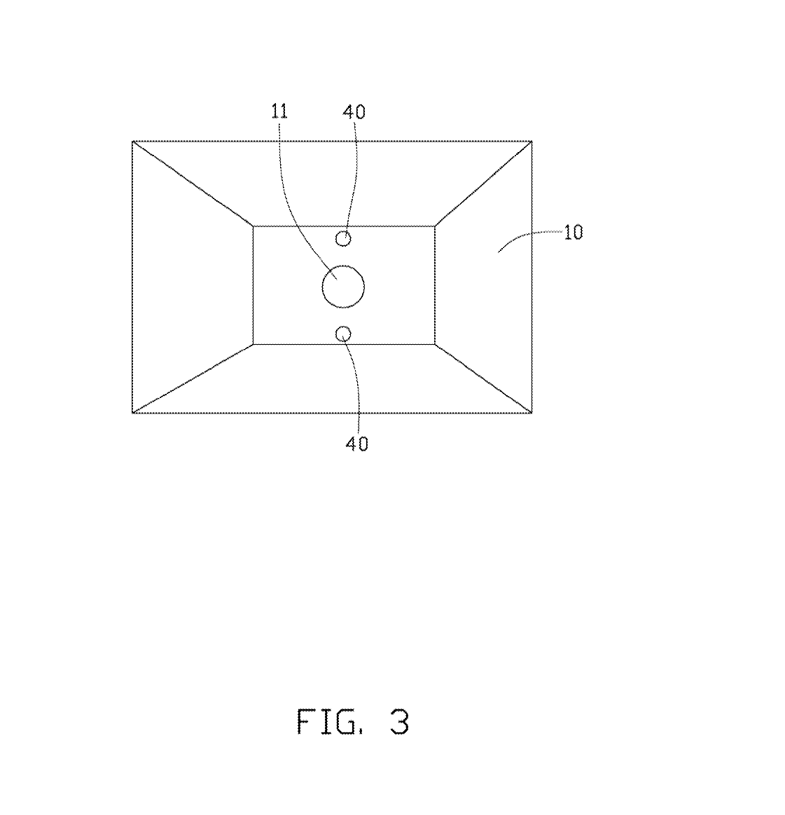

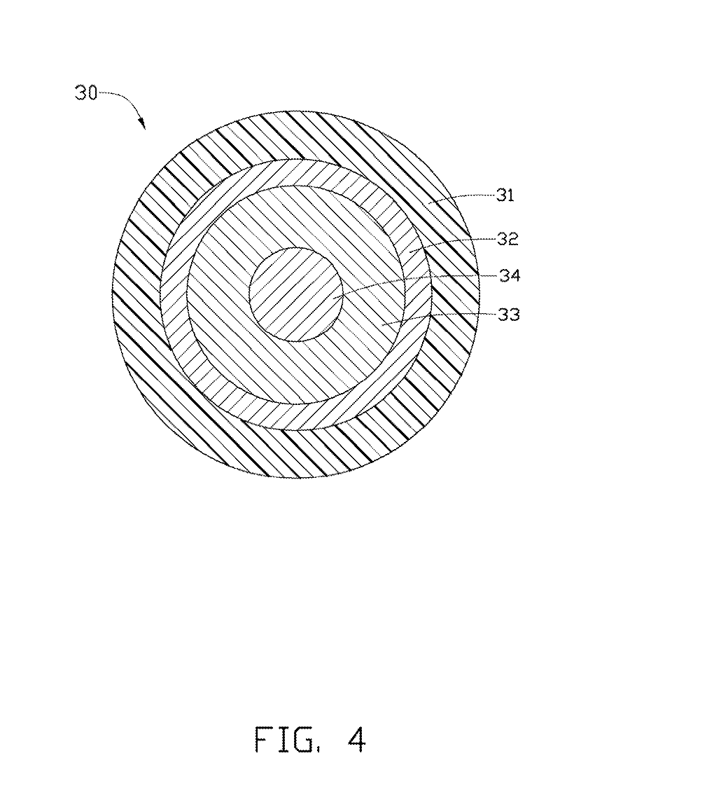

Referring to FIGS. 1 to 4, an embodiment of a test device 100 for testing high frequency electromagnetic interference (EMI), includes a probe device 110, an amplifier 120, and a measuring body 130. The measuring body 130 is a known measuring device, such as a spectrum analyzer, and theory of the measuring device is known. The probe device 110 includes a horn antenna 10, a spacer 50, a cylindrical handle 20, a coaxial cable 30, a pair of screws 80, and a pair of nuts 90. In one embodiment, the amplifier 120 is a high frequency signal amplifier.

The horn antenna 10 includes an opening defined therein, and a bottom plate 40 opposite to the opening. A center hole 41 is defined in a center of the bottom plate 40. A connecting portion 11 is formed at a center of an inner side of the bottom plate 40. A pair of fixing holes 42 is defined in the bottom plate 40 of the horn antenna 10, respectively located at opposite sides of the center hole 41. A center hole 51 is defined in a center of the spacer 50. A pair of fixing holes 52 is defined in the spacer 50, respectively located at opposite sides of the center hole 51. The handle 20 includes a fixing piece 60 perpendicularly set on an end thereof. A pair of fixing holes 62 is defined in the fixing piece 60, respectively located at opposite sides of the handle 20. A through hole 23 is defined in a center of the handle 20 along an axis of the handle 20 and extends through the fixing piece 60. In one embodiment, the horn antenna 10 is a microwave antenna. The spacer 50 is an insulated spacer, and is placed between the handle 20 and the horn antenna 10. The handle 20 is made of metal material.

The coaxial cable 30 includes a protective layer 31, a shielding layer 32, an insulating layer 33, and a line core 34.

In assembly, a first end of the cable 30 sequentially extends through the through hole 23 of the handle 20, the center hole 51 of the spacer 50, and the center hole 41 of the bottom plate 40 of the horn antenna 10 to engage with the connecting portion 11 of the horn antenna 10. A second end of the cable 30 is connected to the amplifier 120, which is connected to the measuring body 130. The screws 80 sequentially extend through the fixing holes 62 of the fixing piece 60, the fixing holes 52 of the spacer 50, and the fixing holes 42 of the bottom plate 40 of the horn antenna 10, to engage in the nuts 90.

In use, the horn antenna 10 of the probe device 110 can be used to measure EMI in an electronic device by holding the handle 20 and pointing the opening of the horn antenna 10 at the electronic device. When the horn antenna 10 receives EMI signals, the coaxial cable 30 transmits a corresponding signal to the amplifier 120 to be amplified and then transmits the amplified signal to the measuring body 110 to be processed for measuring and output to a display or indicator of some kind included with the measuring body 110 (not shown).

It is to be understood, however, that even though numerous characteristics and advantages of the present disclosure have been set forth in the foregoing description, together with details of the structure and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A test device for testing high frequency electromagnetic interference (EMI), the test device comprising:
a measuring body; and
a probe device comprising:
a horn antenna capable of detecting high frequency EMI;
a handle attached to the antenna for feasibly holding the horn antenna; and
a cable, a first end of the cable connected to the horn antenna, and a second end of the cable connected to the measuring body.

2. The test device of claim 1, further comprising an amplifier connected between the second end of the cable and the measuring body, to amplify a signal transmitted from the horn antenna and output the amplified signal to the measuring body.

3. The test device of claim 2, wherein the probe device further comprises a spacer arranged between the horn antenna and the handle.

4. The test device of claim 3, wherein the spacer is made of an insulated material.

5. The test device of claim 3, wherein a fixing piece is attached to the handle, the horn antenna comprises a bottom plate, a pair of fixing holes is defined in each of the fixing piece, the spacer, and the bottom plate of the horn antenna, a pair of screws extends through the fixing holes of the fixing piece, the spacer, and the horn antenna to engage in a pair of nuts.

6. The test device of claim 5, wherein the handle is cylindrical.

7. The test device of claim 6, wherein a connecting portion is formed at an inner side of the bottom plate of the horn antenna, a through hole is defined in a center of the handle along an axis of the handle and extends through the fixing piece, a center hole is defined in a center of each of the spacer and the bottom plate of the horn antenna, the first end of the cable extends through the through hole of the handle, the center holes of the spacer and the antenna to engage with the connecting portion.

8. The test device of claim 1, wherein the horn antenna is a microwave antenna.
